(19) United States
(12) Patent Application Publication
(10) Pub. No.: US 2025/0056726 A1
(43) Pub. Date: Feb. 13, 2025

(54) WIRING BOARD, ELECTRONIC COMPONENT MOUNTING PACKAGE USING WIRING BOARD, AND ELECTRONIC MODULE

(71) Applicant: KYOCERA CORPORATION, Kyoto-shi, Kyoto (JP)

(72) Inventor: Yoshiki KAWAZU, Kyoto-shi (JP)

(73) Assignee: KYOCERA CORPORATION, Kyoto-shi, Kyoto (JP)

(21) Appl. No.: 18/723,114

(22) PCT Filed: Dec. 21, 2022
(86) PCT No.: PCT/JP2022/047139

§ 371 Date: Jun. 21, 2024

(30) Foreign Application Priority Data
Dec. 23, 2021 (JP) 2021-209543

(51) Int. Cl. H05K 1/18; H01L 23/02; H05K 1/02

(52) U.S. Cl. CPC H05K 1/182; H05K 1/0213; H01L 23/02; H05K 2201/09036

(57) ABSTRACT

A wiring board includes first and second insulating layers and first and second line conductors. The first insulating layer includes first upper and lower surfaces, and one or more opening parts each including an opening at the first upper surface. The second insulating layer includes second upper and lower surfaces. The second upper surface overlaps the first lower surface. The first line conductor is positioned on the second upper surface. The second line conductor is positioned on the second upper surface with a gap with respect to the first line conductor and extends along the first line conductor. At least one of the line conductors is signal wiring. The second insulating layer includes a first region including the first and second line conductors and a region positioned between the line conductors in plan view. The one or more opening parts overlap the first region in plan view.

### TECHNICAL FIELD

The present disclosure relates to a wiring board, an electronic component mounting package using a wiring board, and an electronic module.

### BACKGROUND OF INVENTION

In recent years, wireless communication devices and optical communication devices have been desired to operate at a higher frequency in order to increase speed and to transmit a large amount of information. Specifically, a known wiring structure to transmit a radio-frequency signal at high speed includes a wiring board including a differential wiring structure (Patent Literature 1).

### CITATION LIST

### Patent Literature

Patent Literature 1: Japanese Unexamined Patent Application Publication No. 2020-17830

### SUMMARY

In an embodiment of the present disclosure, a wiring board includes a first insulating layer, a second insulating layer, a first line conductor, and a second line conductor. The first insulating layer includes a first upper surface, a first lower surface, and one or more opening parts each including an opening at the first upper surface. The second insulating layer includes a second upper surface and a second lower surface, and the second upper surface overlaps the first lower surface. The first line conductor is positioned on the second upper surface. The second line conductor is positioned on the second upper surface with a gap between the first line conductor and the second line conductor, the second line conductor extending along the first line conductor. At least one of the first line conductor or the second line conductor is signal wiring. The second insulating layer includes a first region including the first line conductor, the second line conductor, and a region positioned between the first line conductor and the second line conductor in plan view. The one or more opening parts overlap the first region in plan view.

In an embodiment of the present disclosure, an electronic component mounting package includes the wiring board including the above configuration, a substrate, and a frame body positioned on an upper surface of the substrate.

In an embodiment of the present disclosure, an electronic module includes the electronic component mounting package including the above configuration, an electronic component positioned on the upper surface of the substrate and electrically connected to the wiring board, and a lid body positioned on the frame body to cover an internal portion of the electronic component mounting package.

### BRIEF DESCRIPTION OF THE DRAWINGS

FIG. 1 is an exploded perspective view of a wiring board according to a first embodiment of the present disclosure.

FIG. 2 is an exploded perspective view of the wiring board illustrated in FIG. 1 when seen from a different angle.

FIG. 3A is a perspective view of the wiring board illustrated in FIG. 1.

FIG. 3B is a perspective view of the wiring board illustrated in FIG. 3A, where a first insulating layer is illustrated to be transparent.

FIG. 4A is a plan view of the wiring board illustrated in FIG. 1.

FIG. 4B is a plan view of the wiring board illustrated in FIG. 4A, where the first insulating layer is illustrated to be transparent.

FIG. 5A is a sectional view taken along line X1-X1 of the wiring board illustrated in FIG. 4A.

FIG. 5B is a sectional view illustrating a shape of Variation 1 of an opening part of a wiring board in an embodiment.

FIG. 5C is a sectional view illustrating a shape of Variation 2 of an opening part of a wiring board in an embodiment.

FIG. 6 is a sectional view illustrating a shape of Variation 3 of an opening part of the wiring board illustrated in FIG. 4A.

FIG. 7A is a plan view of a wiring board according to a second embodiment of the present disclosure.

FIG. 7B is a plan view of the wiring board illustrated in FIG. 7A, where the first insulating layer is illustrated to be transparent.

FIG. 8A is a sectional view taken along line X2-X2 of the wiring board illustrated in FIG. 7A.

FIG. 8B is a sectional view illustrating a shape of a variation of an opening part of the wiring board illustrated in FIG. 7A.

FIG. 9A is a sectional view of an opening part of a wiring board in a third embodiment of the present disclosure.

FIG. 9B is a sectional view illustrating a shape of Variation 1 of an opening part of the wiring board in the third embodiment.

FIG. 9C is a sectional view illustrating a shape of Variation 2 of an opening part of the wiring board in the third embodiment.

FIG. 10 is an exploded perspective view of a wiring board according to a fourth embodiment of the present disclosure.

FIG. 11A is a perspective view of the wiring board illustrated in FIG. 10, where a fourth insulating layer is illustrated to be transparent.

FIG. 11B is a sectional view taken along line X3-X3 of the wiring board illustrated in FIG. 11A.

FIG. 12 is an exploded perspective view of an electronic component mounting package and an electronic module including the wiring board according to the first embodiment of the present disclosure.

### DESCRIPTION OF EMBODIMENTS

### <Wiring Board Configuration>

Hereinafter, several exemplary embodiments of the present disclosure are described with reference to the drawings. Note that any direction may be defined as an upper direction or a lower direction regarding each of a wiring board, an electronic component mounting package using a wiring board, and an electronic module. However, for convenience, an orthogonal coordinate system xyz is defined, and a positive side in a z-direction is assumed as the upper direction. Below, a first direction indicates, for example, an x-direction in the drawings. In the present disclosure, plan view is a concept including planar transparent view.

### First Embodiment

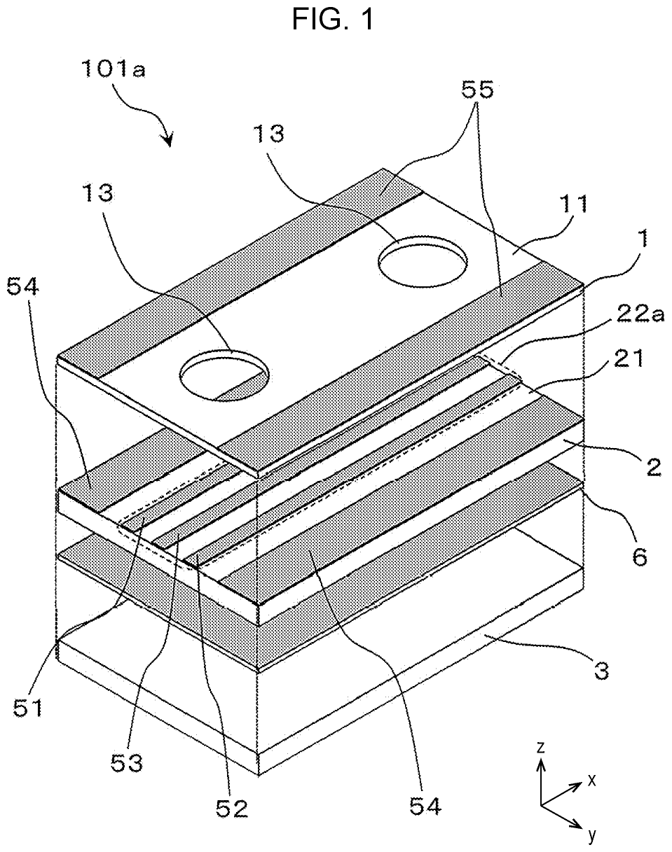

According to a first embodiment of the present disclosure, a wiring board 101a is described with reference to FIGS. 1 to 6.

The wiring board 101a includes at least a first insulating layer 1, a second insulating layer 2, a first line conductor 51, and a second line conductor 52. The wiring board 101a may further include a third line conductor 53, a pair of fourth line conductors 54, a pair of fifth line conductors 55, an insulating film 7, a third insulating layer 3, and a ground conductor layer 6.

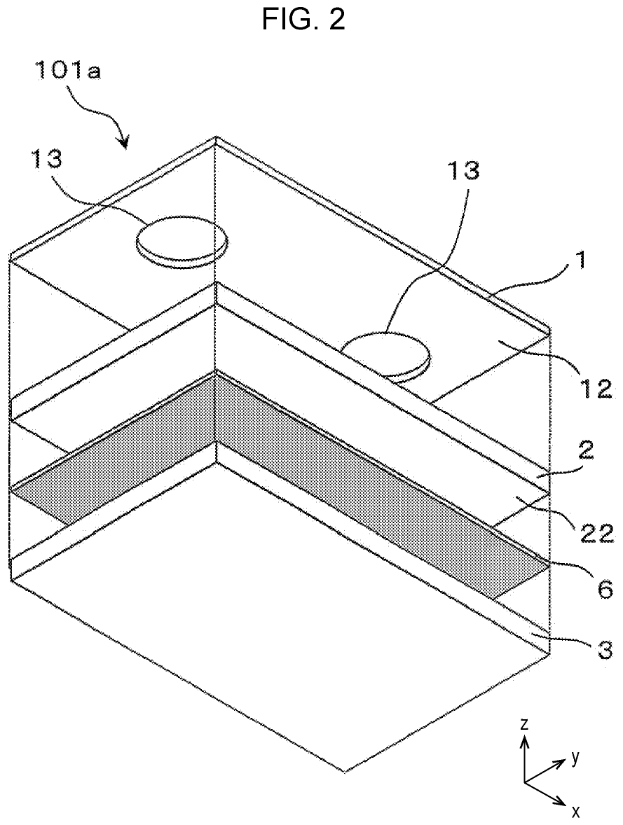

As illustrated in FIGS. 1 and 2, the first insulating layer 1 includes a first upper surface 11, a first lower surface 12, and one or more opening parts 13 including an opening at the first upper surface 11. As a material for the first insulating layer 1, for example, a dielectric material, such as a ceramic material, for example, an aluminum oxide-based sintered body, a mullite-based sintered body, a silicon carbide-based sintered body, an aluminum nitride-based sintered body, or a silicon nitride-based sintered body, or a glass-ceramic material can be used.

The first insulating layer 1 may include a configuration in which multiple insulating layers are laminated on one another. For example, the first insulating layer 1 may have a rectangular shape in plan view, a size of 4 mm×4 mm to 50 mm×50 mm, and a thickness of 1 mm to 10 mm.

The second insulating layer 2 includes a second upper surface 21 and a second lower surface 22. As illustrated in FIGS. 1 and 2, the second upper surface 21 is positioned to overlap the first lower surface 12 of the first insulating layer 1. A material for the second insulating layer 2 may be the same as or different from the material for the first insulating layer 1, and for example, a material the same as and/or similar to the material for the first insulating layer 1 described above can be used. The second insulating layer 2 may include a configuration in which multiple insulating layers are laminated on one another. For example, the second insulating layer 2 may have a rectangular shape in plan view, a size of 4 mm×4 mm to 50 mm×50 mm, and a thickness of 1 mm to 10 mm. The thickness of the second insulating layer 2 may be the same as or different from the thickness of the first insulating layer 1.

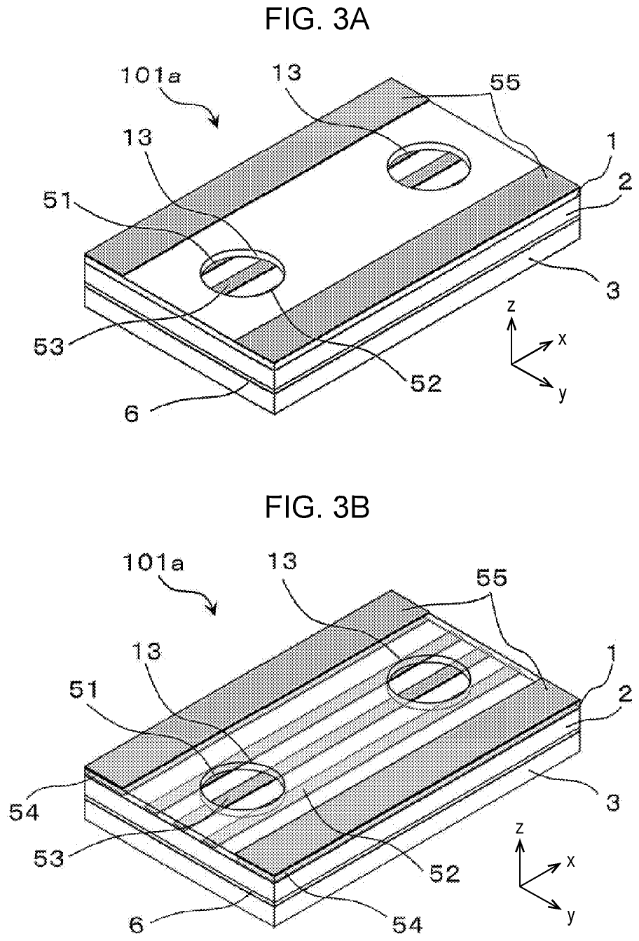

As illustrated in FIGS. 1 and 3B, the first line conductor 51 is positioned on the second upper surface 21 of the second insulating layer 2 and extends in the first direction in an embodiment. Examples of a material for the first line conductor 51 include a metal material, such as gold, silver, copper, nickel, tungsten, molybdenum, and manganese. The first line conductor 51 may be formed by sintering of metal paste on the second upper surface 21, or formed by using a thin-film formation technology, such as a vapor deposition method or a spattering method. Metal plating, such as nickel plating or gold plating may be formed on a surface of the first line conductor 51. For example, the first line conductor 51 has a width of 0.05 mm to 2 mm, and a length of 1.5 mm to 25 mm. For example, the first line conductor 51 has a thickness of 0.01 to 0.1 mm. Note that the width, length, and thickness of the first line conductor 51 as used herein can indicate a y-direction dimension, an x-direction dimension, and a z-direction dimension of the first line conductor 51, respectively. A width/length/thickness of each of the second line conductor 52 and the third line conductor 53 described later can also be defined in the same manner.

As illustrated in FIGS. 1 and 3B, the second line conductor 52 is positioned on the second upper surface 21 of the second insulating layer 2 and extends along the first line conductor 51 with a gap between the first line conductor 51 and the second line conductor 52. That is, the second line conductor 52 extends in parallel to the first line conductor 51 and extends in the first direction in an embodiment. A material for the second line conductor 52 may be the same as or different from the material for the first line conductor 51 and include, for example, a material the same as and/or similar to the material for the first line conductor 51 described above. The second line conductor 52 may be formed in a method the same as and/or similar to that for the first line conductor 51 described above. For example, the second line conductor 52 has a width of 0.05 mm to 2 mm, and a length of 1.5 mm to 25 mm. For example, the second line conductor 52 has a thickness of 0.01 to 0.1 mm.

At least one of the first line conductor 51 and the second line conductor 52 is signal wiring. That is, one of the first line conductor 51 and the second line conductor 52 may be ground wiring. The first line conductor 51 and/or the second line conductor 52 may have curves at intermediate positions thereof. The first line conductor 51 and/or the second line conductor 52 may have widths changed at intermediate positions thereof. The third line conductor 53, the pair of fourth line conductors 54, and the pair of fifth line conductors 55, which will be described later, may also have curves and/or widths changed at intermediate positions thereof.

In an embodiment, the first line conductor 51 and the second line conductor 52 are respective signal wiring lines which transmit a signal and are a pair of differential signal wiring lines which transmit a differential signal. In this case, current flows in opposite directions from each other, and thus magnetic fluxes cancel out each other. Therefore, EMI noise caused by a radio-frequency signal can be reduced, and transmission of the radio-frequency signal can be smoother.

As described above, in the first embodiment, the third line conductor 53 may further be provided. As illustrated in FIGS. 1, 3B, and 4B, the third line conductor 53 is positioned between the first line conductor 51 and the second line conductor 52 on the second upper surface 21 of the second insulating layer 2 with a gap between the first line conductor 51 and the second line conductor 52 and a gap between the second line conductor 52 and the third line conductor 53. The third line conductor 53 extends along the first line conductor 51 and the second line conductor 52. That is, the third line conductor 53 extends in the first direction. A material for the third line conductor 53 may be the same as or different from the material for the first line conductor 51 and include, for example, a material the same as or similar to the material for the first line conductor 51 described above. The third line conductor 53 may be formed in a method the same as or similar to that for the first line conductor 51 described above. For example, the third line conductor 53 has a width of 0.05 mm to 2 mm, and a length of 1.5 mm to 25 mm. For example, the third line conductor 53 has a thickness of 0.01 to 0.1 mm. In the first embodiment, the third line conductor 53 is ground wiring.

When the wiring board 101a includes the third line conductor 53, signal transmission can have reduced loss. The loss occurs when the wiring such as the first line conductor 51 or the second line conductor 52 includes a bent.

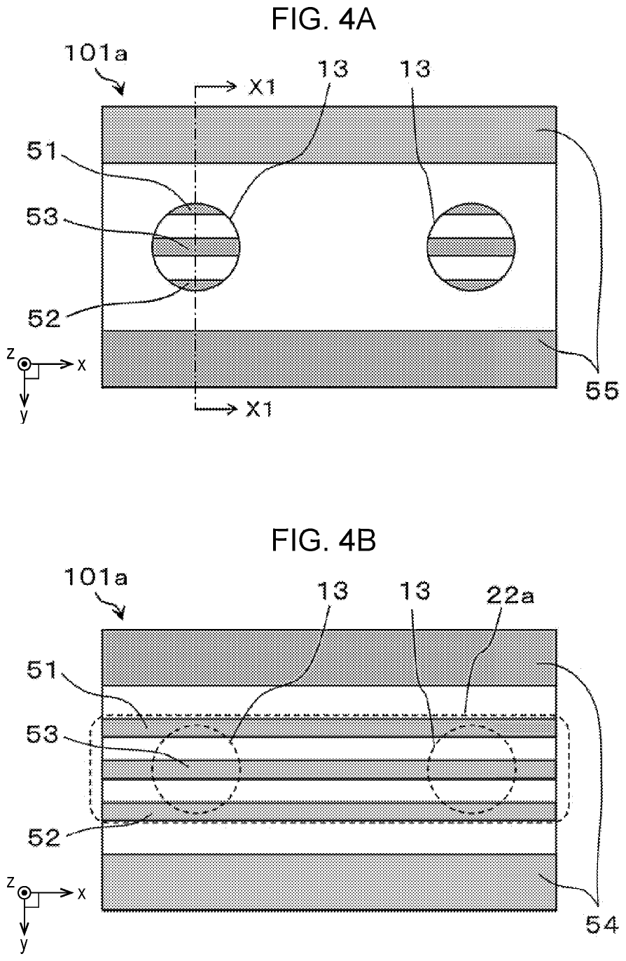

When seen in plan view, as illustrated in FIGS. 1 and 4B, the second insulating layer 2 includes a first region 22a including the first line conductor 51, the second line conductor 52, and a region between the first line conductor 51 and the second line conductor 52. That is, the first region 22a includes the first line conductor 51, the second line conductor 52, and the region sandwiched between the first line conductor 51 and the second line conductor 52. An outer edge of the first region 22a may match outer edges of the first line conductor 51 and the second line conductor 52 at an outermost side in the y-direction.

In the first embodiment, as described above, the first insulating layer 1 includes the opening part 13 including the opening at the first upper surface 11. As illustrated in FIGS. 1 and 4B, the opening part 13 is positioned to overlap the first region 22a in plan view. The opening part 13 is filled with air, or a dielectric material such as a resin material or a glass material. The opening part 13 has a lower permittivity than that of the first insulating layer 1 and the second insulating layer 2.

In the wiring board 101a, when the first line conductor 51 and the second line conductor 52 are positioned between the first insulating layer 1 and the second insulating layer 2 in sectional view in the x-direction or the y-direction so as to transmit a higher frequency signal, reflection loss increases in each line conductor. That is, when the first line conductor 51 and the second line conductor 52 are inner layer wiring, impedance may decrease since the first insulating layer 1 and the second insulating layer 2 vertically sandwiching the first line conductor 51 and the second line conductor 52 have high permittivity. However, in an embodiment, since the first insulating layer 1 includes the opening part 13 positioned as described above, the wiring board 101a can mitigate decrease in impedance in the first line conductor 51 and the second line conductor 52. Accordingly, by using the wiring board 101a, an electronic component mounting package 100 and an electronic module 10 capable of reducing loss in transmission of a radio-frequency signal can be provided.

When the gap between the first line conductor 51 and the third line conductor 53 and the gap between the second line conductor 52 and the third line conductor 53 are small, an impedance value is more likely to decrease. However, in an embodiment, the first insulating layer 1 includes the opening part 13 at the position overlapping the first region 22a, thereby being capable of mitigating decrease in impedance. Therefore, in comparison to a case without the opening part 13, while improving reduction in impedance, the first line conductor 51, the second line conductor 52, and the third line conductor 53 can be provided close to one another. Accordingly, both of reduction in impedance and reduction in size in the wiring board 101a are achievable. Moreover, signal transmission can have smaller loss, and crosstalk can be less likely to occur.

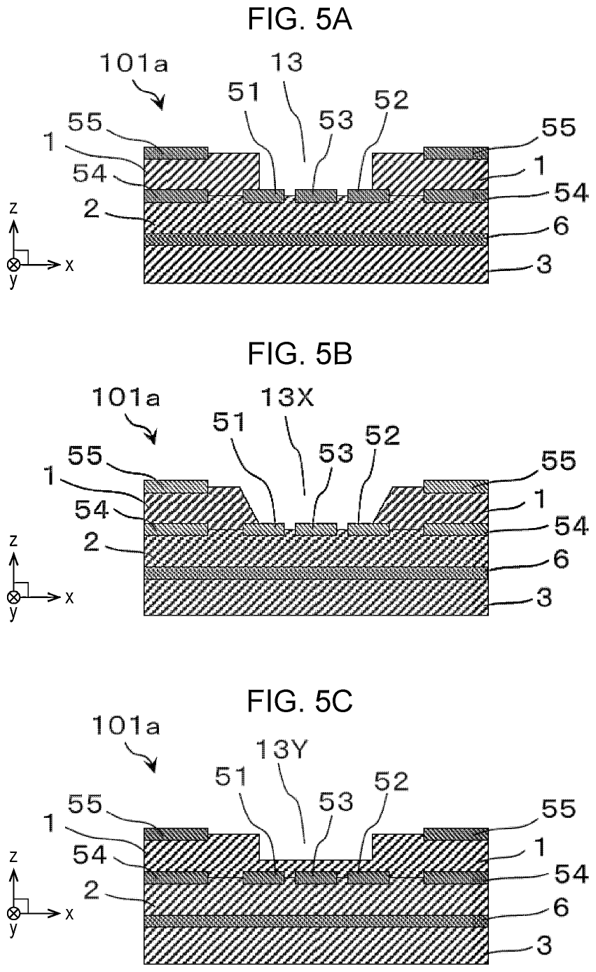

A shape of the opening part 13 is described. As illustrated in FIG. 5A, the opening part 13 may penetrate from the first upper surface 11 to the first lower surface 12. As illustrated in FIG. 4A, for example, the opening part 13 has a circular shape in plan view, a diameter of 0.05 mm to 2 mm, and a height of 0.05 mm to 5 mm. Note that the opening part may have an ellipse shape, a square shape, or a rectangular shape with rounded corners in plan view.

When the opening part 13 penetrates from the first upper surface 11 to the first lower surface 12, in comparison to a case in which the opening part 13 has a recess shape including an opening at the first upper surface 11, the first insulating layer 1 with high permittivity is not positioned on the first line conductor 51 and/or the second line conductor 52 which serves as a signal line. Therefore, decrease in impedance can further be mitigated.

FIG. 5B is a diagram for explaining a shape of Variation 1 (opening part 13X) of the opening part 13 according to an embodiment. FIG. 5C is a diagram for explaining a shape of Variation 2 (opening part 13Y) of the opening part 13 according to an embodiment. FIGS. 5B and 5C are diagrams corresponding to a sectional view taken along line X1-X1 in FIG. 4A. As illustrated in FIG. 5B, the opening part 13 includes a side wall having a tapered shape in sectional view in the x-direction or the y-direction. The opening part 13 having such a shape achieves the same effect as described above. When the opening part 13 has the shape as illustrated in FIG. 5C, the first line conductor 51 and the second line conductor 52 are not exposed. Therefore, providing metal plating on the wiring is unnecessary, which reduces occurrence of connection failure due to the metal plating. The opening part 13 may include a side wall having an inversely tapered shape and a stepped shape in sectional view in the x-direction or the y-direction. As illustrated in FIG. 5C, the opening part 13 may not penetrate to reach the first lower surface 12, but may have a recess shape including an opening at the first upper surface 11. The opening part 13 having such a shape achieves the same effect as described above. In the opening part 13 having such a shape, in comparison to the case in which the opening part 13 penetrates the first insulating layer 1, the first insulating layer 1 remains on the first line conductor 51 and the second line conductor 52. Therefore, each of the first line conductor 51 and the second line conductor 52 can be less likely to short-circuit.

Positioning of the opening part 13 is described. When seen in plan view, the opening part 13 may be positioned at least between the first line conductor 51 and the second line conductor 52 in the first region 22a.

When seen in plan view, the opening part 13 may be positioned to at least overlap the first line conductor 51 and the second line conductor 52 in the first region 22a. In this case, in sectional view in the x-direction or the y-direction, the first insulating layer 1 having high permittivity can include a smaller portion positioned on the first line conductor 51 and the second line conductor 52. Therefore, decrease in impedance can further be mitigated.

As illustrated in FIGS. 1, 3A, 3B, 4A, and 4B, the first insulating layer 1 may include two or more opening parts 13 arranged in a direction in which the first line conductor 51 and the second line conductor 52 extend, specifically in the first direction. In this case, in comparison to a case of including only one opening part 13 having a shape along outer edges of the respective line conductors, providing the opening part 13 during manufacture becomes easier. Therefore, a ceramic green sheet in an unfired stage can be less likely to be damaged. Furthermore, decrease in impedance can efficiently be mitigated.

In an embodiment, as described above, the pair of fourth line conductors 54, the pair of fifth line conductors 55, the insulating film 7, the third insulating layer 3, and the ground conductor layer 6 may be provided.

The pair of fourth line conductors 54 is positioned to sandwich the first line conductor 51 and the second line conductor 52 on the second upper surface 21 of the second insulating layer 2 with a gap between the pair of fourth line conductors 54 and each of the first line conductor 51 and the second line conductor 52, and extends along the first line conductor 51. That is, the pair of fourth line conductors 54 extends in parallel to the first line conductor 51 and extends in the first direction in an embodiment. A material for the pair of fourth line conductors 54 may be the same as or different from the material for the first line conductor 51 and include, for example, a material the same as and/or similar to the material for the first line conductor 51 described above. The pair of fourth line conductors 54 may be formed in a method the same as or similar to that for the first line conductor 51 described above. For example, each one of the pair of fourth line conductors 54 has a width of 0.05 mm to 2 mm, and a length of 1.5 mm to 25 mm. For example, each one of the pair of fourth line conductors 54 has a thickness of 0.01 to 0.1 mm.

When the wiring board 101a includes the pair of fourth line conductors 54, crosstalk and/or resonance can be less likely to occur. The crosstalk and/or resonance are caused by spreading of electric field distribution exceeding a desired range during transmission of a radio-frequency signal.

When the wiring board 101a includes the pair of fourth line conductors 54, each of the first line conductor 51 and the second line conductor 52 may be a pair of differential signal wiring lines.

When the wiring board 101a includes the pair of fourth line conductors 54, each of the first line conductor 51 and the second line conductor 52 may be a signal line, the third line conductor 53 may be ground wiring, and the pair of fourth line conductors 54 may be ground wiring.

The pair of fifth line conductors 55 is positioned on the first upper surface 11 of the first insulating layer 1 to overlap the pair of fourth line conductors 54 in planar transparent view. A material for the pair of fifth line conductors 55 may be the same as or different from the material for the first line conductor 51 and include, for example, the same material as that for the first line conductor 51 described above. The pair of fifth line conductors 55 may be formed in a method the same as and/or similar to that for the first line conductor 51 described above. For example, each one of the pair of fifth line conductors 55 has a width of 0.05 mm to 2 mm, and a length of 1.5 mm to 25 mm. For example, each one of the pair of fifth line conductors 55 has a thickness of 0.01 to 0.1 mm.

When the wiring board 101a includes the pair of fifth line conductors 55, crosstalk and/or resonance can be less likely to occur. The crosstalk and/or resonance are caused by spreading of electric field distribution exceeding a desired range during transmission of a radio-frequency signal.

The ground conductor layer 6 is positioned on the second lower surface 22 of the second insulating layer 2. Examples of a material for the ground conductor layer 6 include a metal material, such as tungsten, molybdenum, and manganese, and nickel plating or gold plating may be applied to a surface of the ground conductor layer 6. When the wiring board 101a includes the ground conductor layer 6, electrolytic coupling can be stronger, and thereby crosstalk and/or resonance can be less likely to occur. The crosstalk and/or resonance are caused by spreading of electric field distribution exceeding a desired range during transmission of a radio-frequency signal.

The third insulating layer 3 is positioned at a downside of the ground conductor layer 6. A material for the third insulating layer 3 may be the same as or different from the material for the first insulating layer 1, and for example, a material the same as and/or similar to that for the first insulating layer 1 described above can be used. The third insulating layer 3 may include a configuration in which multiple insulating layers laminated on one another. For example, the third insulating layer 3 may have a rectangular shape in plan view, a size of 4 mm×4 mm to 50 mm×50 mm, and a thickness of 1 mm to 10 mm.

The pair of fourth line conductors 54, the pair of fifth line conductors 55, and the ground conductor layer 6 may electrically be connected to one another through a via or the like. In this case, a ground potential can be strengthened, and thereby crosstalk and/or resonance can be less likely to occur. The crosstalk and/or resonance are caused by spreading of electric field distribution exceeding a desired range during transmission of a radio-frequency signal.

Vias which electrically connect the pair of fourth line conductors 54, the pair of fifth line conductors 55, and the ground conductor layer 6 one another may be formed as follows, for example. First, a through-hole is provided to a ceramic green sheet in an unfired stage of each of the first insulating layer 1 and the second insulating layer 2, and the through-hole is filled with a metal paste. The metal paste is a metal material the same as or similar to the material for the pair of fourth line conductors 54, the pair of fifth line conductors 55, and/or the ground conductor layer 6. The respective ceramic green sheets including through-holes filled with the metal paste are stacked on and pressure bonded with one another, and co-fired to provide vias. Note that the through-hole described above can be formed by, for example, perforation processing, such as mechanical punching processing using a metal pin, or processing using laser light.

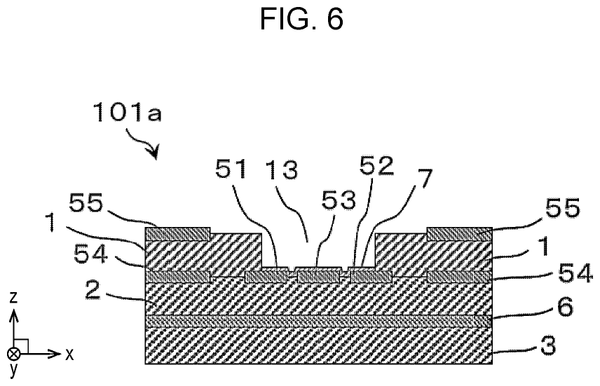

A variation of the wiring board 101a according to the first embodiment is described with reference to FIG. 6. In the first embodiment, as illustrated in FIG. 6, the wiring board 101a may include the insulating film 7 on the first line conductor 51 and the second line conductor 52. A material for the insulating film 7 may include a ceramic (for example, aluminum coat) or a resin. The insulating film 7 can be provided on the first line conductor 51 and the second line conductor 52 by screen printing. Particularly, when the opening part 13 penetrates from the first upper surface 11 to the second lower surface 22, upon the insulating film 7 being provided, each of the first line conductor 51 and the second line conductor 52 can be less likely to short-circuit.

As illustrated in FIG. 6, when the wiring board 101a includes the third line conductor 53, the wiring board 101a may include the insulating film 7 on the first line conductor 51, the second line conductor 52, and the third line conductor 53. In such a configuration, each of the first line conductor 51, the second line conductor 52, and the third line conductor 53 can be less likely to short-circuit.

### Second Embodiment

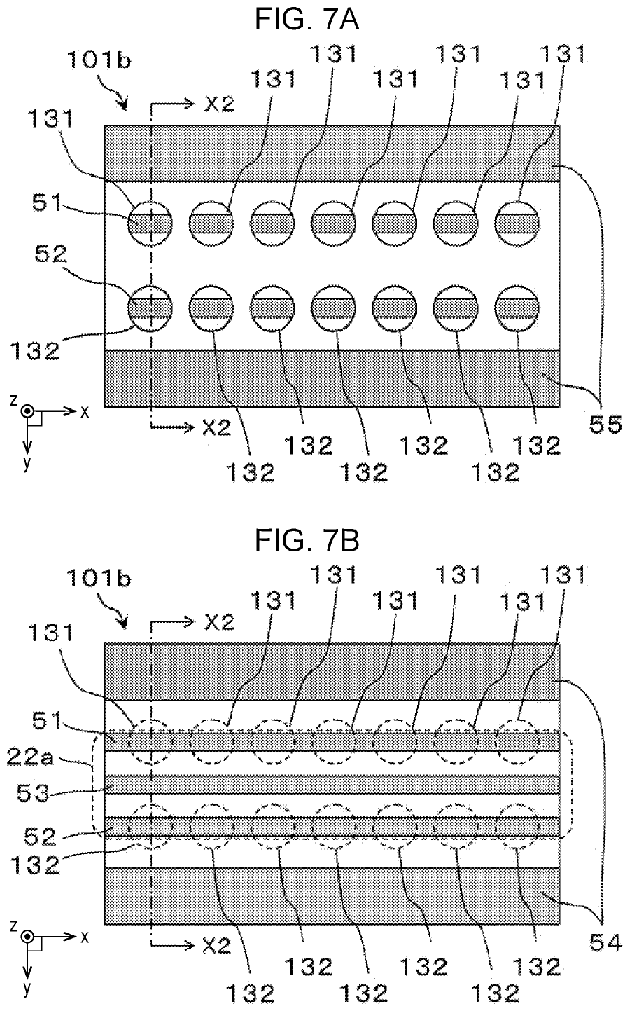

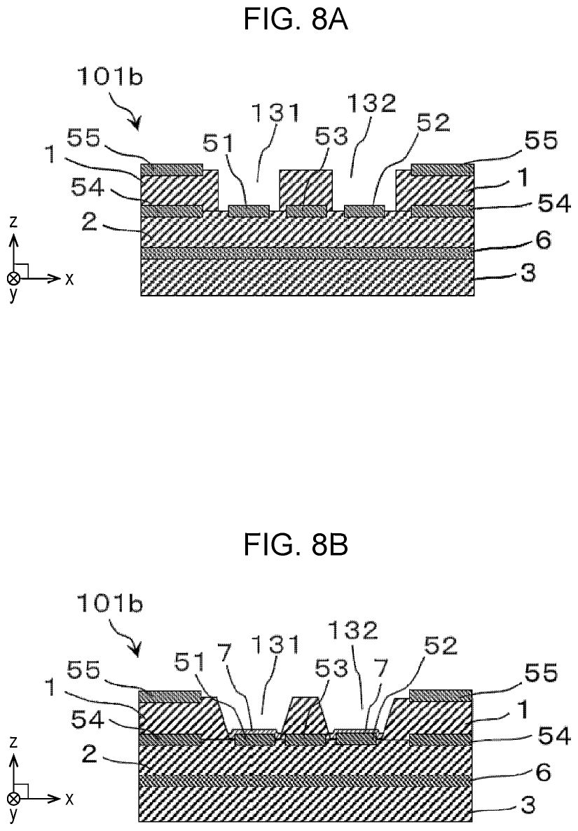

According to a second embodiment of the present disclosure, a wiring board 101b is described with reference to FIGS. 7A, 7B, 8A, and 8B. Note that, below, among configurations of the second embodiment, only configurations different from the configurations of the first embodiment are described, and configurations other than the different configurations are denoted by reference characters the same as and/or similar to those for the first embodiment to omit description thereof.

According to the second embodiment, the wiring board 101b includes the opening part 13 having a different shape when compared to the first embodiment. That is, in the second embodiment, as illustrated in FIGS. 7A, 7B, and 8A, the opening part 13 may include a first opening part 131 and a second opening part 132. More specifically, as illustrated in FIG. 7B, when seen in plan view, the first opening part 131 is positioned to overlap the first line conductor 51, and the second opening part 132 is positioned to overlap the second line conductor 52. In such a configuration, when the first line conductor 51 and the second line conductor 52 are respective signal wiring lines which transmit a signal, and are a pair of differential signal wiring lines which transmit a differential signal, decrease in impedance can be mitigated further efficiently.

The first opening part 131 and the second opening part 132 may have shapes the same as or different from one another. The shapes of the first opening part 131 and the second opening part 132 can be changed in accordance with an impedance value required for the wiring board 101b.

All of multiple first opening parts 131 do not necessarily have the same shape as each other. Moreover, all of multiple second opening parts 132 do not necessarily have the same shape as each other.

The shapes of the first opening part 131 and the second opening part 132 adjacent to each other in the y-direction may be the same. In this case, arrangement of impedance values in the first line conductor 51 and the second line conductor 52 becomes easy.

Note that also in the second embodiment, as with the first embodiment, as illustrated in FIG. 8B, the wiring board 101b may include the insulating film 7 on the first region 22a. In the second embodiment, since the first insulating layer 1 is positioned on the third line conductor 53, the insulating film 7 is positioned on the first line conductor 51 and the second line conductor 52, but not on the third line conductor 53.

### Third Embodiment

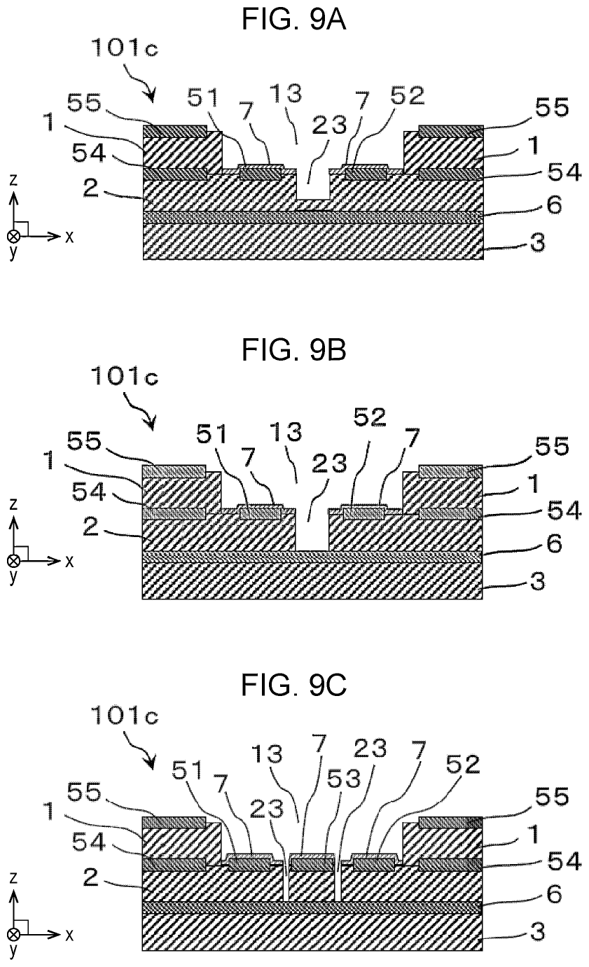

According to a third embodiment of the present disclosure, a wiring board 101c is described with reference to FIGS. 9A to 9C. Note that, below, among configurations of the third embodiment, only configurations different from the configurations of the first embodiment are described, and configurations other than the different configurations are denoted by reference characters the same as and/or similar to those for the first embodiment to omit description thereof.

According to the third embodiment, the wiring board 101c is different from the first embodiment in that the wiring board 101c further includes a recess part 23 which will be described below. That is, in the third embodiment, as illustrated in FIG. 9A, the second insulating layer 2 may include one or more recess parts 23 including openings at the second upper surface 21. Specifically, as illustrated in FIG. 9A, the recess part 23 is positioned between the first line conductor 51 and the second line conductor 52.

The recess part 23 is filled with air, or a dielectric material such as a resin material or a glass material. The recess part 23 has lower permittivity than that of the first insulating layer 1 and the second insulating layer 2. Note that, in the third embodiment, although the recess part 23 of the second insulating layer 2 is positioned to overlap the opening part 13 of the first insulating layer 1 in plan view, the position of the recess part 23 is not limited to such a position. When the recess part 23 of the second insulating layer 2 is positioned to overlap the opening part 13 of the first insulating layer 1 in plan view, adjustment of permittivity is easier than a case in which the recess part 23 is not positioned to overlap the opening part 13. Therefore, decrease in impedance can be mitigated.

For example, the recess part 23 may have a circular shape in plan view, a diameter of 0.05 mm to 2 mm, and a height of 0.05 mm to 5 mm. The recess part 23 may have an ellipse shape, a square shape, or a rectangular shape with rounded corners in plan view. The recess part 23 may have a tapered shape, inversely tapered shape, and a stepped shape in sectional view in the x-direction or the y-direction. FIGS. 9B and 9C are views illustrating variations of the recess part 23 in the third embodiment. As illustrated in the drawings, the recess part 23 may penetrate from the second upper surface 21 to the second lower surface 22 of the second insulating layer 2, or the recess part 23 may include two or more recess parts 23 positioned between the first line conductor 51 and the second line conductor 52. When the recess part 23 penetrates the second insulating layer 2, the second insulating layer 2 can have a smaller portion positioned between the first line conductor 51 and the second line conductor 52. Therefore, in comparison to the case in which the recess part 23 does not penetrate the second insulating layer 2, decrease in impedance can further be mitigated.

In the wiring board 101c, when the first line conductor 51 and the second line conductor 52 are inner layer wiring so as to transmit a higher frequency signal, impedance decreases since the first insulating layer 1 and the second insulating layer 2 vertically sandwiching the first line conductor 51 and the second line conductor 52 have high permittivity. However, providing the recess part 23 as in the third embodiment can mitigate decrease in impedance in the first line conductor 51, the second line conductor 52, or the third line conductor 53 in the wiring board 101c, and can further provide the electronic component mounting package 100 and the electronic module 10 capable of reducing loss in transmission of a radio-frequency signal.

Moreover, when the gap between the first line conductor 51, the second line conductor 52, and the third line conductor 53 is small, an impedance value easily decreases. Therefore, due to the first region 22a including the recess part 23, decrease in impedance can be mitigated. Furthermore, in comparison to a case without the recess part 23, the first line conductor 51, the second line conductor 52, and the third line conductor 53 can be provided close to one another. Accordingly, reduction in size of the wiring board 101c is achievable.

### Fourth Embodiment

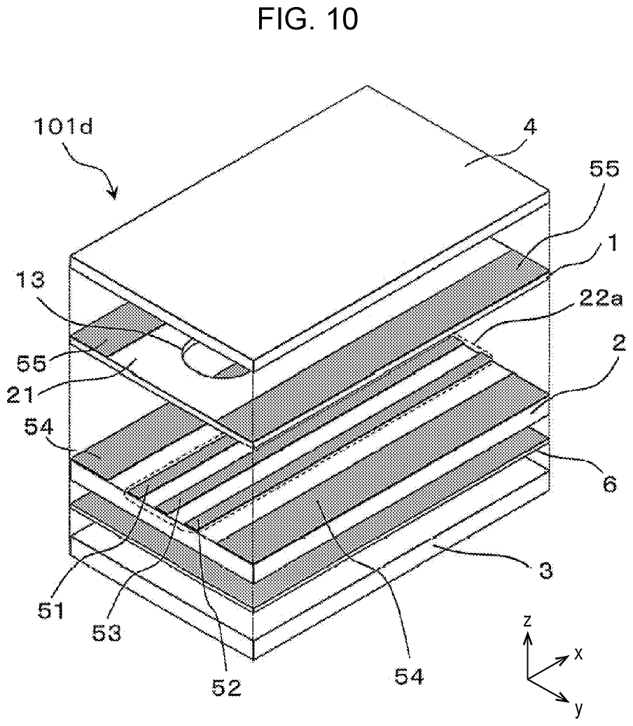

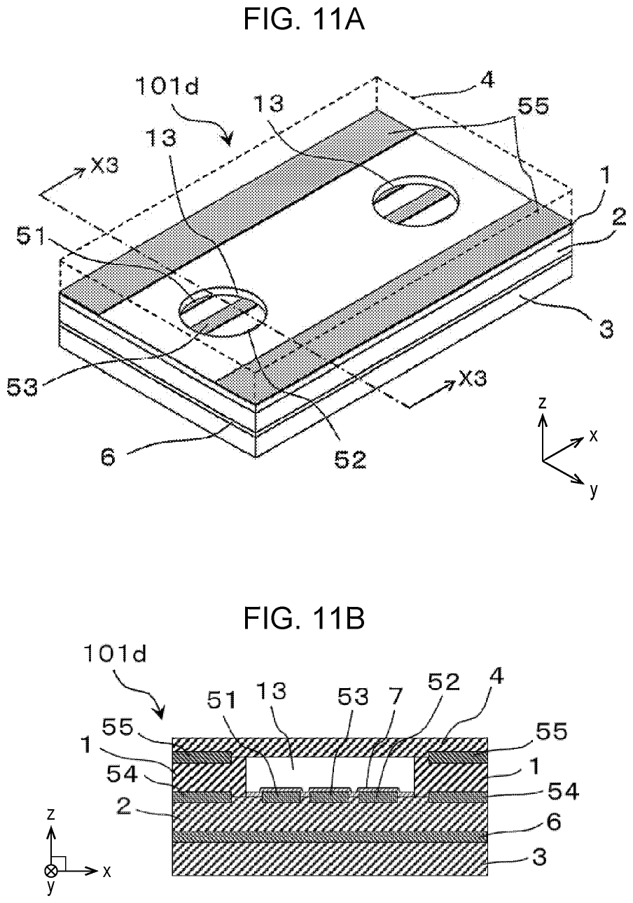

According to a fourth embodiment of the present disclosure, a wiring board 101d is described with reference to FIGS. 10, 11A, and 11B. Note that, below, among configurations of the fourth embodiment, only configurations different from the configurations of the first embodiment are described, and configurations other than the different configurations are denoted by reference characters the same as and/or similar to those for the first embodiment to omit description thereof.

According to the fourth embodiment, the wiring board 101d is different from the first embodiment in that the wiring board 101d further includes a fourth insulating layer 4 described below.

As illustrated in FIGS. 10, 11A, and 11B, the fourth insulating layer 4 is positioned on the first upper surface 11 of the first insulating layer 1. A material for the fourth insulating layer 4 may be the same as or different from the material for the first insulating layer 1, and for example, a material the same as that for the first insulating layer 1 described above can be used. The fourth insulating layer 4 may include a configuration in which multiple insulating layers are laminated on one another. For example, the fourth insulating layer 4 may have a rectangular shape in plan view, a size of 4 mm×4 mm to 50 mm×50 mm, and a thickness of 1 mm to 10 mm.

When the wiring board 101d further includes the fourth insulating layer 4, the wiring board 101d can further include wiring on an upper surface of the fourth insulating layer 4. When such a wiring board 101d is disposed to surround, together with a frame body 103, an outer edge of an upper surface of a substrate 102, a seal ring 105 or a lid body 106 may be provided to the upper surface of the fourth insulating layer 4.

### <Method for Manufacturing Wiring Board>

According to an embodiment of the present disclosure, a method for manufacturing the wiring board 101a is described. Note that the method for manufacturing the wiring board 101a according to the embodiment of the present disclosure is not limited to the method described below, but may use a 3D printer to manufacture the wiring board 101a.

(1) First, a plurality of green sheets is formed. Specifically, for example, a mixture is obtained by adding and mixing organic binder, plasticizer, a solvent, or the like to ceramic powder, such as boron nitride, aluminum nitride, silicon nitride, silicon carbide, beryllium oxide, or the like. Then, the mixture is formed to be layered to fabricate multiple green sheets. Next, the multiple green sheets are processed using a die or the like to prepare the multiple green sheets formed to have respective external shapes of the first insulating layer 1, the second insulating layer 2, and the third insulating layer 3 in plan view. In a case of forming the wiring board including the fourth insulating layer 4 as in the fourth embodiment of the present disclosure, a green sheet formed to have an external shape of the fourth insulating layer is additionally prepared. Next, the opening part 13 is provided to the green sheet which becomes the first insulating layer 1 by using a die, a laser, or the like. Note that in a case of forming the wiring board including the recess part 23, similarly to the opening part 13, the recess part 23 is provided to the green sheet which becomes the second insulating layer 2.

When the opening part 13 does not penetrate the first insulating layer 1, a green sheet including a through-hole and a green sheet not including a through-hole are laminated on one another to make the first insulating layer 1. Also when the recess part 23 does not penetrate the second insulating layer 2, the recess part 23 can be made in a method the same as and/or similar to the method for making the opening part 13 of the first insulating layer 1. When the opening part 13 penetrates the first insulating layer 1, the opening part 13 may be provided, by punching using a die, or by using a laser or the like, to the green sheet formed to have the external shape of the first insulating layer 1. In this process, the green sheet having the external shape of each of the first insulating layer 1, the second insulating layer 2, the third insulating layer 3, and the fourth insulating layer 4 may be formed with a through-hole by using a die, a laser, or the like. The through-hole becomes a via or the like.

(2) High-melting-point metal powder such as tungsten or molybdenum is prepared, and metal paste is prepared by adding and mixing organic binder, plasticizer, a solvent, or the like to the prepared powder. Next, the metal paste is printed in a given pattern on the multiple green sheets formed to have the respective external shapes of the first insulating layer 1, the second insulating layer 2, the third insulating layer 3, and the fourth insulating layer 4, to form the first line conductor 51, the second line conductor 52, the third line conductor 53, the pair of fourth line conductors 54, and the pair of fifth line conductors 55. Note that the metal paste may include glass or ceramics to increase bonding strength with respect to each insulating layer. A via or the like can be formed by filling the through-hole with the metal paste to be the via or the like. The through-hole is made in the aforementioned process.

(3) Next, a method for making the ground conductor layer 6 is described. For example, when the ground conductor layer 6 is a metalized layer made of metal with a high melting point, such as tungsten, molybdenum, or manganese, the ground conductor layer 6 can be formed as follows. That is, first, metal paste is made by kneading metal powder having a high melting point, together with an organic solvent and binder to be well mixed up. Then, the metal paste is printed, in a method such as screen printing, at a given position of the ceramic green sheet to become a lower surface of the second insulating layer 2 or an upper surface of the third insulating layer 3.

(4) The multiple green sheets formed to have the respective external shapes of the first insulating layer 1, the second insulating layer 2, the third insulating layer 3, and the fourth insulating layer 4 are stacked on one another in such a manner that outer edge portions of the multiple green sheets match an outer edge portion of the ground conductor layer 6. Accordingly, a green sheet stacking body is formed. Note that after the formation of the green sheet stacking body, metal paste may be printed in a given pattern to form the pair of fifth line conductors 55 and/or another wiring line.

(5) The green sheet stacking body is fired to sinter the multiple green sheets, thus obtaining the wiring board 101a.

### <Configuration of Electronic Component Mounting Package>

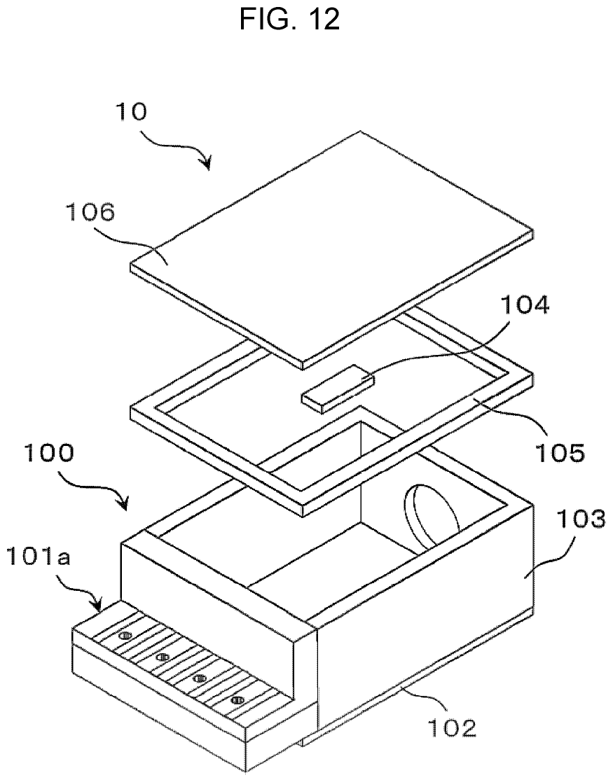

As illustrated in FIG. 12, the electronic component mounting package 100 includes the wiring board 101a, the substrate 102, and the frame body 103. The frame body 103 is bonded to an upper surface of the substrate 102, and the wiring board 101a is fixed to the frame body 103.

The substrate 102 includes the upper surface. For example, the substrate 102 has a quadrilateral shape in plan view, a size of 10 mm×10 mm to 50 mm×50 mm, and a thickness of 0.5 mm to 20 mm. Examples of a material for the substrate 102 include a metal material, such as copper, iron, tungsten, molybdenum, nickel, or cobalt, or an alloy containing these metal materials. In this case, the substrate 102 may be a single metal plate or a multilayer body including a plurality of laminated metal plates. When the material of the substrate is the metal material described above, in order to reduce oxidation corrosion, a surface of the substrate 102 may be formed with a plating layer of nickel, gold, or the like, by using an electroplating method or an electroless plating method. A material for the substrate 102 may be an insulating material, for example, a ceramic material, such as an aluminum oxide-based sintered body, a mullite-based sintered body, a silicon carbide-based sintered body, an aluminum nitride-based sintered body, a silicon nitride-based sintered body, or glass ceramics.

The frame body 103 is positioned on the upper surface of the substrate 102 and protects an electronic component 104 positioned inside in plan view. That is, the frame body 103 surrounds the electronic component 104 when seen in plan view. The frame body 103 may be positioned along an outer edge of the upper surface of the substrate 102 or may be positioned at an inner side of the outer edge of the upper surface of the substrate 102. The frame body 103 does not necessarily surround the entirety of the outer edge of the upper surface of the substrate 102. That is, as illustrated in FIG. 12, in an embodiment, the frame body 103 is not positioned at one side of the outer edge of the upper surface of the substrate 102. The frame body 103 and the wiring board 101a surround the outer edge of the upper surface of the substrate 102.

A material for the frame body 103 may be, for example, a metal material, such as copper, iron, tungsten, molybdenum, nickel, or cobalt, or an alloy containing these metal materials. The material for the frame body 103 may be an insulating material, for example, a ceramic material, such as an aluminum oxide-based sintered body, a mullite-based sintered body, a silicon carbide-based sintered body, an aluminum nitride-based sintered body, a silicon nitride-based sintered body, or glass ceramics.

The frame body 103 may be bonded to the substrate 102 with a brazing material or the like interposed therebetween. Note that a material of the brazing material is, for example, silver, copper, gold, aluminum, or magnesium, and may contain an additive such as nickel, cadmium, or phosphorus.

### <Configuration of Electronic Module>

As illustrated in FIG. 12, the electronic module 10 includes the electronic component mounting package 100, the electronic component 104, and the lid body 106. The electronic module 10 may include the seal ring 105.

The electronic component 104 may be, for example, a component which performs signal processing, such as conversion of an optical signal into an electrical signal, or conversion of an electrical signal into an optical signal. The electronic component 104 is positioned on the upper surface of the substrate 102 and is accommodated in the electronic component mounting package 100.

Examples of the electronic component 104 include an optical semiconductor element, such as a semiconductor laser (LD: laser diode) or a photo diode (PD), a semiconductor integrated circuit element, and a sensor element such as an optical sensor. For example, the electronic component 104 can be formed by using a semiconductor material, such as gallium arsenide, or gallium nitride.

The lid body 106 is positioned on the frame body 103 to cover an internal portion of the electronic component mounting package 100, and protects, together with the frame body 103, the electronic component 104. For example, the lid body 106 has a quadrilateral shape in plan view, a size of 10 mm×10 mm to 50 mm×50 mm, and a thickness of 0.5 mm to 2 mm. Examples of a material for the lid body 106 include a metal material, such as iron, copper, nickel, chromium, cobalt, molybdenum, or tungsten, or an alloy combining multiple materials among these metal materials. By application of metalworking such as rolling processing or punching processing to an ingot of such a metal material, the metal member which configures the lid body 106 can be fabricated.

The seal ring 105 has a function to bond the lid body 106 and the frame body 103. The seal ring 105 is positioned on the frame body 103 to surround the electronic component 104 in plan view. Examples of a material for the seal ring 105 include a metal material, such as iron, copper, silver, nickel, chromium, cobalt, molybdenum, or tungsten, or an alloy combining multiple materials among these metal materials. Note that in a case of not providing the seal ring 105 on the frame body 103, the lid body 106 may be bonded via, for example, a bonding material, such as a solder, a brazing material, glass, or a resin adhesive material.

Note that the present disclosure is not limited to the embodiments, variations, and examples described above, and can variously be changed without departing from the spirit of the present disclosure.

Furthermore, various combinations of the feature parts in each embodiment are not limited to the examples in the embodiments described above, and the respective embodiments can be combined together.

### INDUSTRIAL APPLICABILITY

The present disclosure is applicable to a wiring board, an electronic component mounting package using a wiring board, and an electronic module.

### REFERENCE SIGNS

1 first insulating layer
11 first upper surface
12 first lower surface
13X-Y opening part
131 first opening part
132 second opening part
2 second insulating layer
21 second upper surface
22 second lower surface
22a first region
23a-b recess part
3 third insulating layer
4 fourth insulating layer
51 first line conductor
52 second line conductor
53 third line conductor
54 pair of fourth line conductors
55 pair of fifth line conductors
6 ground conductor layer
7 insulating film
10 electronic module
100 electronic component mounting package
101a-d wiring board
102 substrate
103 frame body
104 electronic component
105 seal ring
106 lid body

1. A wiring board comprising:
a first insulating layer comprising a first upper surface, a first lower surface, and one or more opening parts each comprising an opening at the first upper surface;
a second insulating layer comprising a second upper surface and a second lower surface, the second upper surface overlapping the first lower surface;
a first line conductor positioned on the second upper surface; and
a second line conductor positioned on the second upper surface with a gap between the first line conductor and the second line conductor, the second line conductor extending along the first line conductor, wherein
at least one of the first line conductor or the second line conductor is signal wiring,
the second insulating layer comprises a first region comprising the first line conductor, the second line conductor, and a region positioned between the first line conductor and the second line conductor in plan view, and
the one or more opening parts overlap the first region in plan view.

2. The wiring board according to claim 1, wherein the one or more opening parts penetrate from the first upper surface to the first lower surface.

3. The wiring board according to claim 1, wherein the one or more opening parts are positioned between the first line conductor and the second line conductor in plan view.

4. The wiring board according to claim 1, wherein the one or more opening parts overlap the first line conductor and the second line conductor in plan view.

5. The wiring board according to claim 1, wherein the one or more opening parts comprise a first opening part and a second opening part,
the first opening part overlaps the first line conductor in plan view, and
the second opening part overlaps the second line conductor in plan view.

6. The wiring board according to claim 1, wherein the first insulating layer comprises two or more opening parts arranged in line in a direction in which the first line conductor and/or the second line conductor extend.

7. The wiring board according to claim 1, wherein the second insulating layer comprises, between the first line conductor and the second line conductor, one or more recess parts each comprising an opening at the second upper surface.

8. The wiring board according to claim 1, wherein the first line conductor and the second line conductor are a pair of differential signal wiring lines.

9. The wiring board according to claim 1, further comprising an insulating film on the first line conductor and on the second line conductor.

10. The wiring board according to claim 1, further comprising a third line conductor positioned between the first line conductor and the second line conductor on the second upper surface with a gap between the first line conductor and the third line conductor and a gap between the second line conductor and the third line conductor, the third line conductor extending along the first line conductor and the second line conductor, wherein
the third line conductor is ground wiring, and
the first line conductor and the second line conductor are signal wiring.

11. The wiring board according to claim 10, further comprising an insulating film on the first line conductor, the second line conductor, and the third line conductor.

12. The wiring board according to claim 8, further comprising a pair of fourth line conductors positioned to sandwich the first line conductor and the second line conductor therebetween on the second upper surface with a gap between the pair of fourth line conductors and each of the first line conductor and the second line conductor, the pair of fourth line conductors extending along the first line conductor and the second line conductor, wherein
the pair of fourth line conductors is ground wiring.

13. The wiring board according to claim 12, further comprising a pair of fifth line conductors positioned on the first upper surface, wherein
the pair of fifth line conductors is ground wiring positioned to overlap the pair of fourth conductor lines in plan view.

14. The wiring board according to claim 1, further comprising:
a ground conductor layer positioned on the second lower surface; and
a third insulating layer positioned at a downside of the ground conductor layer.

15. The wiring board according to claim 1, further comprising a fourth insulating layer positioned on the first upper surface.

16. An electronic component mounting package comprising:
a substrate;
a frame body positioned on an upper surface of the substrate; and
the wiring board according to claim 1, wherein the wiring board is fixed to the frame body.

17. An electronic module comprising:
the electronic component mounting package according to claim 16;
an electronic component positioned on the upper surface of the substrate and electrically connected to the wiring board of the electronic component mounting package; and
a lid body positioned on the frame body to cover an internal portion of the electronic component mounting package.
